(19) United States
(12) Patent Application Publication
(10) Pub. No.: US 2018/0275224 A1
(43) Pub. Date: Sep. 27, 2018

(54) GENERATION OF MAGNETIC FIELD PROXY THROUGH RF FREQUENCY DITHERING

(71) Applicant: Lockheed Martin Corporation, Bethesda, MD (US)

(72) Inventors: Arul Manickam, Mount Laurel, NJ (US); Gregory Scott Bruce, Abington, PA (US); William Gnadt, Marlton, NJ (US)

(73) Assignee: Lockheed Martin Corporation, Bethesda, MD (US)

(21) Appl. No.: 15/468,410

(22) Filed: Mar. 24, 2017

(51) Int. Cl. G01R 33/26; G01R 33/60; G01R 33/032

(52) U.S. Cl. CPC G01R 33/26; G01R 33/032; G01R 33/60

(57) ABSTRACT

Methods, apparatuses, and systems for creating a proxy magnetic reference signal by frequency modulating a desired magnetic field proxy modulation onto an RF wave. A RF pulse sequence for an RF excitation source to apply a RF field to the magneto-optical defect center material can be based on a magnetic field proxy modulation and a base RF wave. The magnetic field proxy modulation can be indicative of a proxy magnetic field. A magnetic field measurement from a magneto-optical defect center material can be detected using the optical sensor and can include a proxy magnetic field based on the magnetic field proxy modulation.

### FIELD

The field relates without limitation to magnetometers, and generally for example, to generation of proxy magnetic fields via radiofrequency (RF) dithering.

### BACKGROUND

A number of industrial applications, as well as scientific areas such as physics and chemistry can benefit from magnetic detection and imaging with a device that has extraordinary sensitivity, ability to capture signals that fluctuate very rapidly (bandwidth) all with a substantive package that is extraordinarily small in size and efficient in power. Many advanced magnetic imaging systems can operate in restricted conditions, for example, high vacuum and/or cryogenic temperatures, which can make them inapplicable for imaging applications that require ambient or other conditions. Furthermore, small size, weight and power (SWAP) magnetic sensors of moderate sensitivity, vector accuracy, and bandwidth are valuable in many applications.

### SUMMARY

Some embodiments may include a system having a magnetometer and a controller. The magnetometer may include a magneto-optical defect center material, an optical excitation source, a radiofrequency (RF) excitation source, and an optical sensor. The controller may be configured to activate a radiofrequency (RF) pulse sequence for the RF excitation source to apply a RF field to the magneto-optical defect center material. The RF pulse sequence may be based on a magnetic field proxy modulation and a base RF wave, and the magnetic field proxy modulation may be indicative of a proxy magnetic field. The controller may be further configured to activate an optical pulse sequence for the optical excitation source to apply a laser pulse to the magneto-optical defect center material and acquire in conjunction with the optical pulse sequence a magnetic field measurement from the magneto-optical defect center material using the optical sensor. The magnetic field measurement comprises a proxy magnetic field based on the magnetic field proxy modulation.

In some implementations, the magnetic field proxy modulation may be a sinusoidal magnetic field proxy modulation. In some implementations, the sinusoidal magnetic field proxy modulation may be calculated based on γb₁ sin(2πf₁t), where γ is the electron gyromagnetic ratio for the magneto-optical defect center material, b₁ is a selected projected magnitude for the proxy magnetic field, and f₁ is selected frequency for the proxy magnetic field. In some implementations, the selected projected magnitude for the proxy magnetic field may be between 100 picoTeslas and 1 microTesla. In some implementations, the selected frequency for the proxy magnetic field may be between 0 Hz and 100 kHz. In some implementations, the magnetic field measurement may include magnetic communication data. In some implementations, the magnetic field measurement may include magnetic navigation data. In some implementations, the magnetic field measurement may include magnetic location data. In some implementations, the magneto-optical defect center material may include a diamond having nitrogen vacancies.

Other implementations may relate to a method for operating a magnetometer having a magneto-optical defect center material. The method may include activating a radiofrequency (RF) pulse sequence to apply an RF field to the magneto-optical defect center material and acquiring a magnetic field measurement using the magneto-optical defect center material. The RF pulse sequence may be based on a magnetic field proxy modulation and a base RF wave, and the magnetic field proxy modulation is indicative of a proxy magnetic field. The magnetic field measurement may include a proxy magnetic field based on the magnetic field proxy modulation.

In some implementations, the magnetic field proxy modulation may be a sinusoidal magnetic field proxy modulation. In some implementations, the sinusoidal magnetic field proxy modulation may be calculated based on γb₁ sin(2πf₁t), where γ is the electron gyromagnetic ratio for the magneto-optical defect center material, b₁ is a selected projected magnitude for the proxy magnetic field, and f₁ is a selected frequency for the proxy magnetic field. In some implementations, the selected projected magnitude for the proxy magnetic field may be between 100 picoTeslas and 1 microTesla. In some implementations, the selected frequency for the proxy magnetic field may be between 0 Hz and 100 kHz. In some implementations, the magnetic field measurement may include magnetic communication data. In some implementations, the magnetic field measurement may include magnetic navigation data. In some implementations, the magnetic field measurement may include magnetic location data. In some implementations, the magneto-optical defect center material may include a diamond having nitrogen vacancies.

Yet other implementations may relate to a sensor that includes a magneto-optical defect center material, a radiofrequency (RF) excitation source, and a controller. The controller is configured to activate a radiofrequency (RF) pulse sequence for the RF excitation source to apply a RF field to the magneto-optical defect center material and acquire a magnetic field measurement from the magneto-optical defect center material. The RF pulse sequence may be based on a magnetic field proxy modulation and a base RF wave, and the magnetic field proxy modulation is indicative of a proxy magnetic field. The magnetic field measurement may include a proxy magnetic field based on the magnetic field proxy modulation.

In some implementations, the magnetic field proxy modulation may be a sinusoidal magnetic field proxy modulation. In some implementations, the sinusoidal magnetic field proxy modulation may be calculated based on γb₁ sin(2πf₁t), where γ is the electron gyromagnetic ratio for the magneto-optical defect center material, b₁ is a selected projected magnitude for the proxy magnetic field, and f₁ is selected frequency for the proxy magnetic field. In some implementations, the selected projected magnitude for the proxy magnetic field may be between 100 picoTeslas and 1 microTesla. In some implementations, the selected frequency for the proxy magnetic field may be between 0 Hz and 100 kHz.

Another implementation relates to a magnetometer that includes a magneto-optical defect center material, a radiofrequency (RF) excitation source, an optical sensor, and a controller. The controller may be configured to activate a radiofrequency (RF) pulse sequence for the RF excitation source to apply a RF field to the magneto-optical defect center material and acquire a magnetic field measurement from the magneto-optical defect center material using the optical sensor. The RF pulse sequence may be based on a magnetic field proxy modulation and a base RF wave, and the magnetic field proxy modulation may be indicative of a proxy magnetic field. The magnetic field measurement may include a proxy magnetic field based on the magnetic field proxy modulation. The controller may be further configured to set a value for a flag indicative of passing an initial pass/fail test based on a processed proxy magnetic reference signal determined from the magnetic field measurement.

In some implementations, the magnetic field proxy modulation may be a sinusoidal magnetic field proxy modulation. In some implementations, the sinusoidal magnetic field proxy modulation may be calculated based on γb₁ sin(2πf₁t), where γ is the electron gyromagnetic ratio for the magneto-optical defect center material, b₁ is a selected projected magnitude for the proxy magnetic field, and f₁ is selected frequency for the proxy magnetic field. In some implementations, the selected projected magnitude for the proxy magnetic field may be between 100 picoTeslas and 1 microTesla. In some implementations, the selected frequency for the proxy magnetic field may be between 0 Hz and 100 kHz.

Another implementation relates to a magnetometer that includes a magneto-optical defect center material, a radiofrequency (RF) excitation source, an optical sensor, and a controller. The controller may be configured to activate a radiofrequency (RF) pulse sequence for the RF excitation source to apply a RF field to the magneto-optical defect center material and acquire a magnetic field measurement from the magneto-optical defect center material using the optical sensor. The RF pulse sequence may be based on a magnetic field proxy modulation and a base RF wave, and the magnetic field proxy modulation may be indicative of a proxy magnetic field. The magnetic field measurement may include a proxy magnetic field based on the magnetic field proxy modulation. The controller may be further configured to determine an attenuation value based on a processed proxy magnetic reference signal determined from the magnetic field measurement.

In some implementations, the magnetic field proxy modulation may be a sinusoidal magnetic field proxy modulation. In some implementations, the sinusoidal magnetic field proxy modulation may be calculated based on γb₁ sin(2πf₁t), where γ is an electron gyromagnetic ratio for the magneto-optical defect center material, b₁ is a selected projected magnitude for the proxy magnetic field, and f₁ is selected frequency for the proxy magnetic field. In some implementations, the selected projected magnitude for the proxy magnetic field may be between 100 picoTeslas and 1 microTesla. In some implementations, the selected frequency for the proxy magnetic field may be between 0 Hz and 100 kHz.

Another implementation relates to a magnetometer that includes a magneto-optical defect center material, a radiofrequency (RF) excitation source, an optical sensor, and a controller. The controller may be configured to activate a radiofrequency (RF) pulse sequence for the RF excitation source to apply a RF field to the magneto-optical defect center material and acquire a magnetic field measurement from the magneto-optical defect center material using the optical sensor. The RF pulse sequence may be based on a magnetic field proxy modulation and a base RF wave, and the bia magnetic field proxy modulation may be indicative of a proxy magnetic field. The magnetic field measurement may include a proxy magnetic field based on the magnetic field proxy modulation. The controller may be further configured to determine an estimated calibrated noise floor value based on a processed proxy magnetic reference signal determined from the magnetic field measurement.

In some implementations, the magnetic field proxy modulation may be a sinusoidal magnetic field proxy modulation. In some implementations, the sinusoidal magnetic field proxy modulation may be calculated based on γb₁ sin(2πf₁t), where γ is an electron gyromagnetic ratio for the magneto-optical defect center material, b₁ is a selected projected magnitude for the proxy magnetic field, and f₁ is selected frequency for the proxy magnetic field. In some implementations, the selected projected magnitude for the proxy magnetic field may be between 100 picoTeslas and 1 microTesla. In some implementations, the selected frequency for the proxy magnetic field may be between 0 Hz and 100 kHz.

Other implementations relate to a magnetometer that includes a magneto-optical defect center material, an excitation source, an optical sensor, and a controller. The controller may be configured to activate an energy pulse sequence for the excitation source to apply an energy field to the magneto-optical defect center material and acquire a magnetic field measurement from the magneto-optical defect center material using the optical sensor. The energy pulse sequence may be based on a magnetic field proxy modulation and a base signal, and the magnetic field proxy modulation may be indicative of a proxy magnetic field. The magnetic field measurement may include a proxy magnetic field based on the magnetic field proxy modulation.

In some other implementations, a magnetic field proxy modulation may be a sinusoidal magnetic field proxy modulation. In some implementations, the sinusoidal magnetic field proxy modulation may be calculated based on γb₁ sin(2πf₁t), where γ is the electron gyromagnetic ratio for the magneto-optical defect center material, b₁ is a selected projected magnitude for the proxy magnetic field, and f₁ is selected frequency for the proxy magnetic field. In some implementations, the selected projected magnitude for the proxy magnetic field may be between 100 picoTeslas and 1 microTesla. In some implementations, the selected frequency for the proxy magnetic field may be between 0 Hz and 100 kHz.

### BRIEF DESCRIPTION OF THE DRAWINGS

The details of one or more implementations are set forth in the accompanying drawings and the description below. Other features, aspects, and advantages of the disclosure will become apparent from the description, the drawings, and the claims, in which:

FIG. 1 illustrates a defect center in a diamond lattice;

FIG. 2 illustrates an energy level diagram showing energy levels of spin states for the defect center;

FIG. 3 illustrates a schematic diagram of a defect center magnetic sensor system;

FIG. 4 is a graph illustrating the fluorescence as a function of an applied RF frequency of a defect center along a given direction for a zero magnetic field, and also for a non-zero magnetic field having a component along the defect center axis;

FIG. 5 is a graph illustrating the fluorescence as a function of an applied RF frequency for various orientations of a non-zero magnetic field;

FIG. 6 is a schematic diagram illustrating a magnetic field detection system according to some embodiments;

FIG. 7 is a graphical diagram depicting a Ramsey pulse sequence;

FIG. 8 is a magnetometry curve for an example resonance frequency;

FIG. 9 is a process diagram depicting a process for generating a proxy magnetic reference signal;

FIG. 10 is a process diagram depicting a process for determining a processed proxy magnetic reference signal;

FIG. 11 is a process diagram depicting a process for generating a sensor attenuation curve of external magnetic fields as a function of frequency using proxy magnetic reference signals;

FIG. 12 is a process diagram depicting a process for generating a calibrated noise floor as a function of frequency using proxy magnetic reference signals; and

FIG. 13 is a block diagram depicting a general architecture for a computer system that may be employed to implement various elements of the systems and methods described and illustrated herein.

It will be recognized that some or all of the figures are schematic representations for purposes of illustration. The figures are provided for the purpose of illustrating one or more embodiments with the explicit understanding that they will not be used to limit the scope or the meaning of the claims.

### DETAILED DESCRIPTION

Following below are more detailed descriptions of various concepts related to, and implementations of, methods, apparatuses, and systems for creating a proxy magnetic field by frequency modulating a desired magnetic field proxy modulation onto an RF wave. In the implementations described herein, no actual external magnetic field are created. Magneto-optical defect center sensors may be susceptible to both internal and external or environmental changes such as temperature, DC and near DC magnetic fields, and power variability of the laser and RF. Providing a magnetic signal of known strength and orientation that can be used as a reference can provide a capability to compensate or correct for some of these environmental changes. In addition, a magnetic field proxy modulation can be used to help determine sensor operational status such as current functionality of the sensor and/or current noise or other error levels of the sensor. The use of an external magnetic source to generate a reference magnetic signal of precise field strength and orientation at a particular portion of a magneto-optical defect center material can be difficult. For instance, some current methods to generate a reference magnetic signal may use one or more external magnetic sources (e.g., a Helmholtz coil with RF source and amplification) to generate the magnetic field. In practice, it may be very difficult to precisely create a magnetic field of known strength and orientation at the magneto-optical defect center element using such methods. Additionally, it can be difficult to generate broadband magnetic signals from a single magnetic source due to the bandwidth limitations of most antennas. Instead, as described herein, a frequency modulated magnetic field proxy modulation can be formulated in lieu of an external magnetic source to generate a biasing proxy magnetic field. Such a proxy magnetic field can reliably create a reference magnetic signal of known strength and orientation, which can be used to compensate for environmental conditions. In addition, the proxy magnetic reference signal can be used for initial functional testing of the sensor and/or determination of current noise and/or error levels with the sensor.

The implementations described herein provides methods, systems, and apparatuses to generate proxy magnetic field modulations representative of a magnetic field of known frequency, magnitude, and field orientation. Such proxy magnetic field modulations can be used for off-line, periodic, or real-time calibration; real-time drift compensation; and/or built-in-testing. To produce the desired proxy magnetic field modulation, R(t), a base RF wave used to interrogate the magneto-optical defect center material can be modified by the biasing RF modulation, F(t). A final RF signal, G(t), to be used to generate the RF field at the magneto-optical defect center material can be determined based on the equation G(t)=A cos (2πF(t)t+φ), where A is the amplitude of the carrier, φ is a phase of the carrier, and F(t) is the base RF wave used to interrogate the magneto-optical defect center material modified by a biasing RF modulation based on the magnetic field proxy modulation of F(t)=F_{c}+γR(t), where F_{c} is the frequency of the base RF wave, γ is the electron gyromagnetic ratio for the magneto-optical defect center material, R(t) is the magnetic field proxy modulation and γR(t) is the biasing RF modulation. For a simple magnetic field proxy modulation, R(t)=b₁ sin(2πf₁t) where b₁ is the strength of the proxy signal and f₁ is the frequency of the proxy signal. In other implementations, complex magnetic field proxy modulation scan be implemented where the strength, b(t), or frequency, f(t), varies based on time or other variables. In implementations where the material is a diamond having nitrogen vacancies, the gyromagnetic ratio is approximately 28 GHz/Tesla. The RF field is applied to the magneto-optical defect center material and an optical excitation source, such as a green laser light, is applied to the magneto-optical defect center material. As described below, the when excited by the optical excitation source, the magneto-optical defect centers generate a different wavelength of optical light, such as red fluorescence for a diamond having nitrogen vacancies. The system uses an optical detector to detect the generated different wavelength of optical light. In some instances, a filter may be used to filter out wavelengths of optical light than the wavelength of interest. The system processes the optical light, such as red light, emitting from the magneto-optical defect center material as if the base RF wave, F(t), was not modulated by the desired magnetic field proxy modulation, R(t). Accordingly, the desired magnetic field proxy modulation, R(t), will be present in the output and will appear as an additional reference magnetic field in addition to any other external magnetic fields to which the magneto-optical defect center material is exposed (e.g., the local Earth magnetic field and any other external magnetic fields). The detected optical signal representative of the applied desired magnetic field proxy modulation, R(t), will be superimposed on top of any background environmental magnetic field signals present.

The use of the desired magnetic field proxy modulation, R(t), for the generation of precise proxy reference magnetic fields can be useful in a number of aspects. For instance, the technique does not incur alignment issues between a magnetic transmitter and the magneto-optical defect center material, does not incur drift of the magnetic transmitter, and does not require a magnetic transmitting coil to be integrated into a sensor head for real-time calibration purposes. In addition, the broadband response of the technique can allow for offline or real-time determination of a system transfer function over a magnetic frequency span of several orders of magnitude. The detected signal by the optical detector for the applied desired magnetic field proxy modulation, R(t), can then be used for base line compensation for the magneto-optical defect center sensor. In addition, the desired magnetic field proxy modulation, R(t), can be periodically used in real-time for the generated RF signal, G(t), for periodic compensation for drift, such as due to temperature fluctuations during operation. Moreover, the detected signal by the optical detector for the applied desired magnetic field proxy modulation, R(t), can be used as an initial pass/fail test for the magneto-optical defect center sensor based on if the detected signal by the optical detector for the applied desired magnetic field proxy modulation, R(t), is within a predetermined tolerance range.

Atomic-sized magneto-optical defect centers, such as nitrogen-vacancy (NV) centers in diamond lattices, have excellent sensitivity for magnetic field measurement and enable fabrication of small magnetic sensors. Magneto-optical defect center materials include but are not be limited to diamonds, Silicon Carbide (SiC), Phosphorous, and other materials with nitrogen, boron, carbon, silicon, or other defect centers. The diamond nitrogen vacancy (DNV) sensors are maintained in room temperature and atmospheric pressure and can be even used in liquid environments. A green optical source (e.g., a micro-LED) can optically excite NV centers of the DNV sensor and cause emission of fluorescence radiation (e.g., red light) under off-resonant optical excitation. A magnetic field generated, for example, by a microwave coil can probe triplet spin states (e.g., with mₛ=−1, 0, +1) of the NV centers to split in relation to an external magnetic field projected along the NV axis, resulting in two spin resonance frequencies. The difference between the two spin resonance frequencies can correlate to a measure of the strength of the external magnetic field. A photo detector can measure the fluorescence (red light) emitted by the optically excited NV centers.

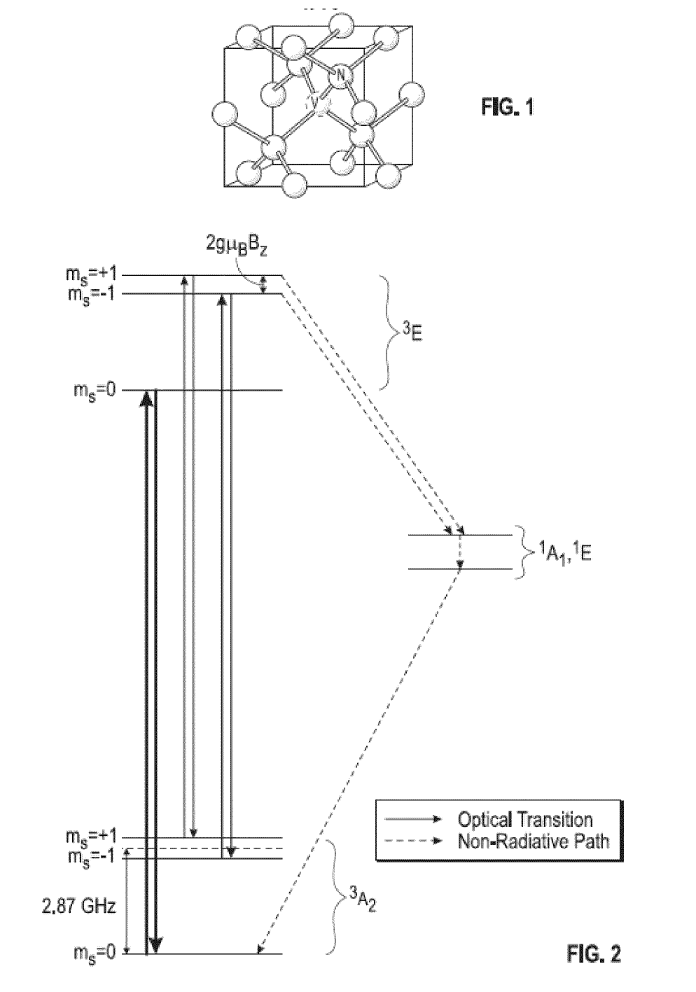

Nitrogen-vacancy centers (NV centers) are defects in a diamond's crystal structure, which can purposefully be manufactured in synthetic diamonds as shown in FIG. 1. In general, when excited by green light and microwave radiation, the NV centers cause the diamond to generate red light. When excited with green light, the NV defect centers generate red light fluorescence. After sufficient time (on order of nanoseconds to microseconds) the fluorescence counts stabilize. When microwave radiation is added, the NV electron spin states are changed, and this results in a change in intensity of the red fluorescence. The changes in fluorescence may be recorded as a measure of electron spin resonance. By measuring the changes, the NV centers may be used to accurately detect the magnetic field strength.

The NV center may exist in a neutral charge state or a negative charge state. Conventionally, the neutral charge state uses the nomenclature NV⁰, while the negative charge state uses the nomenclature NV⁻, which is adopted in this description.

The NV center may have a number of electrons, including three unpaired electrons, each one from the vacancy to a respective of the three carbon atoms adjacent to the vacancy, and a pair of electrons between the nitrogen and the vacancy. The NV center, which is in the negatively charged state, also includes an extra electron.

The NV center has rotational symmetry and, as shown in FIG. 2, has a ground state, which is a spin triplet with ³A₂ symmetry with one spin state mₛ=0, and two further spin states mₛ=+1, and mₛ=−1. In the absence of an external magnetic field, the mₛ=±1 energy levels are offset from the mₛ=0 due to spin-spin interactions, and the mₛ=±1 energy levels are degenerate, i.e., they have the same energy. The mₛ=0 spin state energy level is split from the mₛ=±1 energy levels by an energy of approximately 2.87 GHz for a zero external magnetic field.

Introducing an external magnetic field with a component along the NV axis lifts the degeneracy of the mₛ=±1 energy levels, splitting the energy levels mₛ=±1 by an amount 2gμ_{B}B_{z}, where g is the Lande g-factor, μ_{B} is the Bohr magneton, and B_{z} is the component of the external magnetic field along the NV axis. This relationship is correct to a first order and inclusion of higher order corrections is a straightforward matter.

The NV center electronic structure further includes an excited triplet state ³E with corresponding mₛ=0 and mₛ=±1 spin states. The optical transitions between the ground state ³A₂ and the excited triplet ³E are predominantly spin conserving, meaning that the optical transitions are between initial and final states that have the same spin. For a direct transition between the excited triplet ³E and the ground state ³A₂, a photon of red light is emitted with a photon energy corresponding to the energy difference between the energy levels of the transitions.

There is, however, an alternative non-radiative decay route from the triplet ³E to the ground state ³A₂ via intermediate electron states, which are thought to be intermediate singlet states A, E with intermediate energy levels. Significantly, the transition rate from the mₛ=±1 spin states of the excited triplet ³E to the intermediate energy levels is significantly greater than the transition rate from the mₛ=0 spin state of the excited triplet ³E to the intermediate energy levels. The transition from the singlet states A, E to the ground state triplet ³A₂ predominantly decays to the mₛ=0 spin state over the mₛ=±1 spins states. These features of the decay from the excited triplet ³E state via the intermediate singlet states A, E to the ground state triplet ³A₂ allows that if optical excitation is provided to the system, the optical excitation will eventually pump the NV center into the mₛ=0 spin state of the ground state ³A₂. In this way, the population of the mₛ=0 spin state of the ground state ³A₂ may be “reset” to a maximum polarization determined by the decay rates from the triplet ³E to the intermediate singlet states.

Another feature of the decay is that the fluorescence intensity due to optically stimulating the excited triplet ³E state is less for the mₛ=±1 states than for the mₛ=0 spin state. This is so because the decay via the intermediate states does not result in a photon emitted in the fluorescence band, and because of the greater probability that the mₛ=±1 states of the excited triplet ³E state will decay via the non-radiative decay path. The lower fluorescence intensity for the mₛ=±1 states than for the mₛ=0 spin state allows the fluorescence intensity to be used to determine the spin state. As the population of the mₛ=±1 states increases relative to the mₛ=0 spin, the overall fluorescence intensity will be reduced.

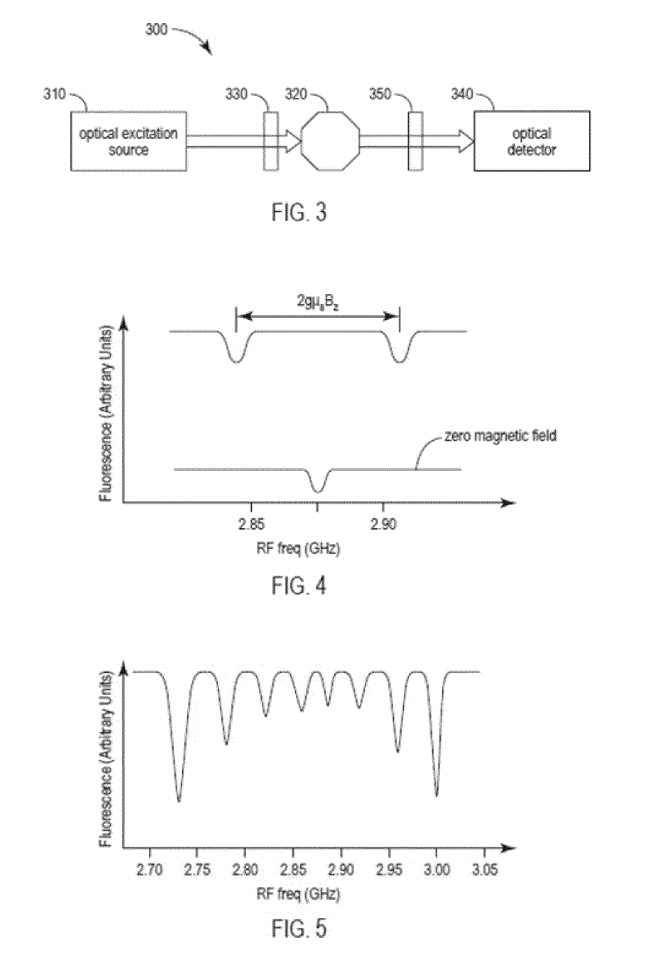

FIG. 3 is a schematic diagram illustrating a NV center magnetic sensor system 300 that uses fluorescence intensity to distinguish the mₛ=±1 states, and to measure the magnetic field based on the energy difference between the mₛ=+1 state and the mₛ=−1 state, as manifested by the RF frequencies corresponding to each state. The system 300 includes an optical excitation source 310, which directs optical excitation to an NV diamond material 320 with NV centers. The system further includes an RF excitation source 330, which provides RF radiation to the NV diamond material 320. Light from the NV diamond may be directed through an optical filter 350 to an optical detector 340.

The RF excitation source 330 may be a microwave coil, for example. The RF excitation source 330, when emitting RF radiation with a photon energy resonant with the transition energy between ground mₛ=0 spin state and the mₛ=+1 spin state, excites a transition between those spin states. For such a resonance, the spin state cycles between ground mₛ=0 spin state and the mₛ=+1 spin state, reducing the population in the mₛ=0 spin state and reducing the overall fluorescence at resonances. Similarly, resonance and a subsequent decrease in fluorescence intensity occurs between the mₛ=0 spin state and the mₛ=−1 spin state of the ground state when the photon energy of the RF radiation emitted by the RF excitation source is the difference in energies of the mₛ=0 spin state and the mₛ=−1 spin state.

The optical excitation source 310 may be a laser or a light emitting diode, for example, which emits light in the green (light having a wavelength such that the color is green), for example. The optical excitation source 310 induces fluorescence in the red, which corresponds to an electronic transition from the excited state to the ground state. Light from the NV diamond material 320 is directed through the optical filter 350 to filter out light in the excitation band (in the green, for example), and to pass light in the red fluorescence band, which in turn is detected by the detector 340. The optical excitation light source 310, in addition to exciting fluorescence in the diamond material 320, also serves to reset the population of the mₛ=0 spin state of the ground state ³A₂ to a maximum polarization, or other desired polarization.

For continuous wave excitation, the optical excitation source 310 continuously pumps the NV centers, and the RF excitation source 330 sweeps across a frequency range that includes the zero splitting (when the mₛ=±1 spin states have the same energy) photon energy of approximately 2.87 GHz. The fluorescence for an RF sweep corresponding to a diamond material 320 with NV centers aligned along a single direction is shown in FIG. 4 for different magnetic field components B_{z} along the NV axis, where the energy splitting between the mₛ=−1 spin state and the mₛ=+1 spin state increases with B_{z}. Thus, the component B_{z} may be determined. Optical excitation schemes other than continuous wave excitation are contemplated, such as excitation schemes involving pulsed optical excitation, and pulsed RF excitation. Examples of pulsed excitation schemes include Ramsey pulse sequence, spin echo pulse sequence, etc.

In general, the diamond material 320 will have NV centers aligned along directions of four different orientation classes. FIG. 5 illustrates fluorescence as a function of RF frequency for the case where the diamond material 320 has NV centers aligned along directions of four different orientation classes and showing 4 sets of Lorentzians corresponding to the four different orientation classes. In this case, the component B_{z} along each of the different orientations may be determined for each set of Lorentzians. These results, along with the known orientation of crystallographic planes of a diamond lattice, allow not only the magnitude of the external magnetic field to be determined, but also the direction of the magnetic field.

While FIG. 3 illustrates an NV center magnetic sensor system 300 with NV diamond material 320 with a plurality of NV centers, in general, the magnetic sensor system may instead employ a different magneto-optical defect center material, with a plurality of magneto-optical defect centers. Magneto-optical defect center materials include but are not be limited to diamonds, Silicon Carbide (SiC), Phosphorous, and other materials with nitrogen, boron, carbon, silicon, or other defect centers. The electronic spin state energies of the magneto-optical defect centers shift with magnetic field, and the optical response, such as fluorescence, for the different spin states is not the same for all of the different spin states. In this way, the magnetic field may be determined based on optical excitation, and possibly RF excitation, in a corresponding way to that described above with NV diamond material.

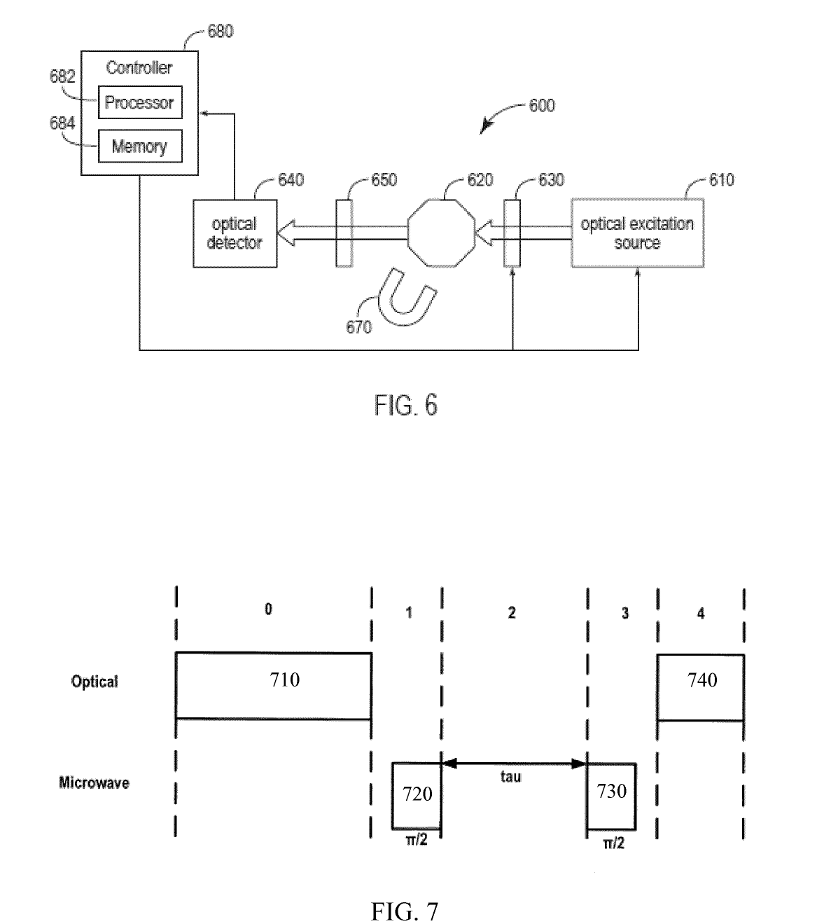

FIG. 6 is a schematic diagram of a system 600 for a magnetic field detection system according to an embodiment.

The system 600 includes an optical light source 610, which directs optical light to an NV diamond material 620 with NV centers, or another magneto-optical defect center material with magneto-optical defect centers. An RF excitation source 630 provides RF radiation to the NV diamond material 620. The system 600 may include a magnetic field generator 670 which generates a magnetic field, which may be detected at the NV diamond material 620, or the magnetic field generator 670 may be external to the system 600. The magnetic field generator 670 may provide a biasing magnetic field.

The system 600 further includes a controller 680 arranged to receive a light detection signal from the optical detector 640 and to control the optical light source 610, the RF excitation source 630, and the magnetic field generator 670. The controller may be a single controller, or multiple controllers. For a controller including multiple controllers, each of the controllers may perform different functions, such as controlling different components of the system 600. The magnetic field generator 670 may be controlled by the controller 680 via an amplifier 660, for example.

The RF excitation source 630 may include a microwave coil or coils, for example. The RF excitation source 630 may be controlled to emit RF radiation with a photon energy resonant with the transition energy between the ground mₛ=0 spin state and the mₛ=±1 spin states as discussed above with respect to FIG. 3, or to emit RF radiation at other nonresonant photon energies.

The controller 680 is arranged to receive a light detection signal from the optical detector 640 and to control the optical light source 610, the RF excitation source 630, and the magnetic field generator 670. The controller 680 may include a processor 682 and a memory 684, in order to control the operation of the optical light source 610, the RF excitation source 630, and the magnetic field generator 670. The memory 684, which may include a nontransitory computer readable medium, may store instructions to allow the operation of the optical light source 610, the RF excitation source 630, and the magnetic field generator 670 to be controlled. That is, the controller 680 may be programmed to provide control.

A Ramsey pulse sequence is a pulsed RF laser scheme that is believed to measure the free precession of the magnetic moment in the diamond material 320, 620 with NV centers, and is a technique that quantum mechanically prepares and samples the electron spin state. According to certain embodiments, the controller 680 controls the operation of the optical light source 610, the RF excitation source 630, and the magnetic field generator 670 to perform Optically Detected Magnetic Resonance (ODMR). The component of the magnetic field B_{z} along the NV axis of NV centers aligned along directions of the four different orientation classes of the NV centers may be determined by ODMR, for example, by using an ODMR pulse sequence according to a Ramsey pulse sequence.

FIG. 7 is an example of a schematic diagram illustrating the Ramsey pulse sequence. As shown in FIG. 7, a Ramsey pulse sequence includes optical excitation pulses and RF excitation pulses over a five-step period. In a first step, during a period 0, a first optical excitation pulse 710 is applied to the system to optically pump electrons into the ground state (i.e., mₛ=0 spin state). This is followed by a first RF excitation pulse 720 (in the form of, for example, a microwave (MW) π/2 pulse) during a period 1. The first RF excitation pulse 720 sets the system into superposition of the mₛ=0 and mₛ=+1 spin states (or, alternatively, the mₛ=0 and mₛ=−1 spin states, depending on the choice of resonance location). During a period 2, the system is allowed to freely precess (and dephase) over a time period referred to as tau (τ). During this free precession time period, the system measures the local magnetic field and serves as a coherent integration. Next, a second RF excitation pulse 730 (in the form of, for example, a MW π/2 pulse) is applied during a period 3 to project the system back to the mₛ=0 and mₛ=+1 basis. Finally, during a period 4, a second optical pulse 740 is applied to optically sample the system and a measurement basis is obtained by detecting the fluorescence intensity of the system. The RF excitation pulses applied are provided at a given RF frequency in relation to the Lorentzians, such as referenced in connection with FIG. 5. The optical light pulse 740 may be provided as a pulse or in a continuous manner throughout periods 0 through 4. Finally, the first optical excitation pulse 710 may be a reset pulse that is applied again to begin another cycle of the Ramsey pulse sequence.

When the first optical excitation pulse 710 is applied again to reset to the ground state at the beginning of another sequence, the readout stage is ended. The Ramsey pulse sequence shown in FIG. 7 may be performed multiple times, wherein each of the MW pulses applied to the system during a given Ramsey pulse sequence includes a different frequency over a frequency range that includes RF frequencies corresponding to different NV center orientations. The magnetic field may be then be determined based on the readout values of the fluorescence as is known for Ramsey pulse sequence techniques.

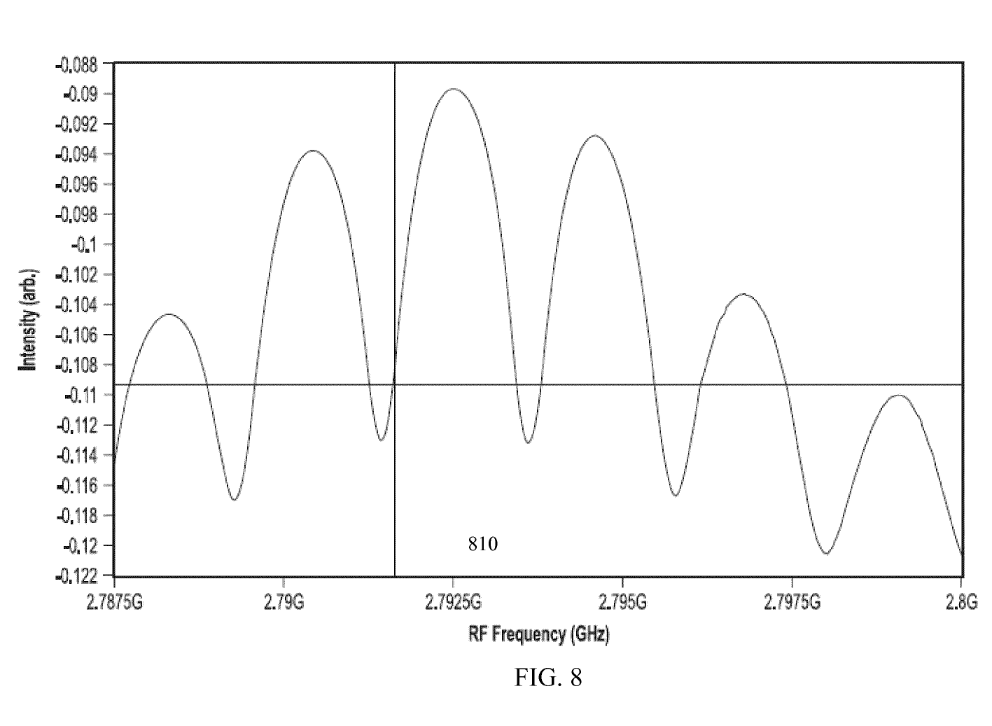

FIG. 8 illustrates a magnetometry curve for an example resonance RF frequency. The magnetometry curve of FIG. 8 corresponds to a spin state transition envelope having a respective resonance frequency for the case where the diamond material has NV centers aligned along a direction of an orientation class. This is similar to one of the 8 spin state transitions shown in FIG. 5 for continuous wave optical excitation where the RF frequency is scanned. The magnetic field component, B_{z}, along the orientation class can be determined based on the resonance frequency relative to the zero external magnetic field frequency, such as 2.87 GHz, in a similar manner to that in FIG. 5. In monitoring the magnetic field, the dimmed luminescence intensity, i.e., the amount the fluorescence intensity diminishes from the case where the spin states have been set to the ground state, of the region having the maximum slope may be monitored. If the dimmed luminescence intensity does not change with time, the magnetic field component does not change. A change in time of the dimmed luminescence intensity indicates that the magnetic field is changing in time, and the magnetic field may be determined as a function of time.

Since a change in resonance RF frequency corresponds to the applied external magnetic field, based on 2gμ_{B}B_{z}, changes in RF frequency can act as a proxy for an external magnetic field. That is, a change in the applied RF frequency based on a desired magnetic field proxy modulation, R(t), to a base RF wave used to interrogate the magneto-optical defect center material, F(t), can be used to mimic the presence of an applied external magnetic field. A final RF signal, G(t), that is then used to generate the RF field at the magneto-optical defect center material can be determined based on the equation G(t)=A cos (2πF(t)t+φ, where A is the amplitude of the carrier, φ is a phase of the carrier, and F(t) is the modulated RF frequency used to interrogate the magneto-optical defect center material modified by the magnetic field proxy modulation of F(t)=F_{c}+γR(t), where F_{c} is the base RF frequency, γ is the electron gyromagnetic ratio for the magneto-optical defect center material, R(t) is the magnetic field proxy modulation and γR(t) is the biasing RF modulation. When the detected optical signal is measured by an optical detector and processed, the applied desired magnetic field proxy modulation, R(t), will be superimposed on top of any background environmental magnetic field signals present. As noted above, introducing an external magnetic field with a component along the NV axis lifts the degeneracy of the mₛ=±1 energy levels, splitting the energy levels mₛ=±1 by an amount 2gμ_{B}B_{z}, where g is the Lande g-factor, μ_{B} is the Bohr magneton, and B_{z} is the component of the external magnetic field along the NV axis. In lieu of the external magnetic field lifting the degeneracy of the mₛ=±1 energy levels, a change in the applied RF energy applied to the magneto-optical defect center material can be used as a proxy for an applied external magnetic field.

In implementations described herein, a sinusoidal dithering to a particular RF interrogation frequency, fᵣ₀, can simulate a sensor response that is equivalent to a sensor response to an external magnetic field with a projected magnitude of b₁ Tesla at a frequency f₁ Hz. The sinusoidal dithering frequency can be determined by fᵣ(t)=fᵣ₀+γb₁ sin(2πf₁t), where γ is the electron gyromagnetic ratio for the material of the magneto-optical defect center element, such as 28 GHz/Tesla for a diamond having nitrogen vacancies. The magnetic field proxy modulation described herein can be applied for both continuous wave or pulsed operation modes for a magnetometer.

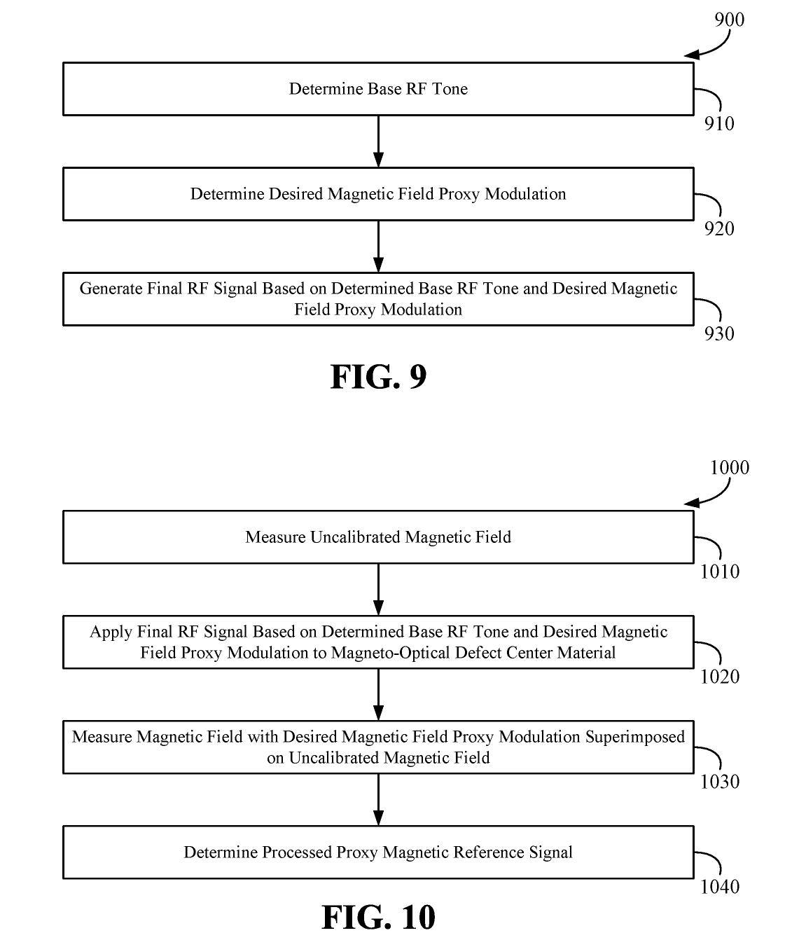

FIG. 9 illustrates a process 900 for generating a proxy magnetic reference signal. The process 900 includes determining a base RF wave (block 910). The base RF wave can be determined by sequentially sweeping through a set of RF frequencies, such as to generate the fluorescence as a function of RF frequency graph of FIG. 5, and selecting a base RF wave, F_{c}(t), based on the resulting data for fluorescence as a function of RF frequency. In some implementations, a selected base RF wave may correspond to an RF frequency where peak slope for each of the spin state transition envelopes.

The process 900 further can include determining the desired magnetic field proxy modulation (block 920). The determination of the desired magnetic field proxy modulation, R(t), may be based on a selected projected magnitude, b₁, Tesla and a selected frequency, f₁, Hz. Using the projected magnitude and selected frequency, the desired magnetic field proxy modulation may be determined as a sinusoid that is dithered about the base RF wave, F_{c}(t). The sinusoid may be γb₁ sin(2πf₁t), where γ is the electron gyromagnetic ratio for the material of the magneto-optical defect center element, such as 28 GHz/Tesla for a diamond having nitrogen vacancies.

The process 900 further can include generating the final RF signal based on the determined base RF wave and the desired magnetic field proxy modulation (block 930). The final RF signal, G(t), can be determined as G(t)=A cos (2πF(t)t+φ), where A is the amplitude of the carrier, φ is a phase of the carrier. F(t) is the base RF wave used to interrogate the magneto-optical defect center material modified by the magnetic field proxy modulation of F(t)=F_{c}+yR(t), where F_{c} is the base RF frequency, γ is the electron gyromagnetic ratio for the magneto-optical defect center material, R(t) is the magnetic field proxy modulation and γR(t) is the biasing RF modulation. For a selected sinusoidal dithering having a projected magnitude, b₁, Tesla and a selected frequency, f₁, Hz about a peak slope frequency, fᵣ₀, the final RF signal fᵣ(t), may be calculated as fᵣ(t)=fᵣ₀+γb₁ sin(2πf₁t).

In some implementations, the process 900 can further include generating an RF field using the final RF signal and a RF excitation source, such as RF excitation source 330, 630, and applying the generated RF field to a NV diamond material 320, 620 or other magneto-optical defect center material.

FIG. 10 illustrates a process 1000 for determining a processed proxy magnetic reference signal based on a desired magnetic field proxy modulation used to generate a final RF signal. The process 1000 includes measuring an uncalibrated magnetic field (block 1010). The uncalibrated magnetic field can be measured by applying a Ramsey pulse sequence for each of a plurality of RF frequencies and storing a corresponding intensity output for each respective frequency of the plurality of RF frequencies. The corresponding baseline uncalibrated magnetic field data can be stored as a baseline curve.

The process 1000 can include applying a final RF signal based on a determined base RF wave and desired magnetic field proxy modulation to a magneto-optical defect center material (block 1020). The final RF signal can be determined based on the process 900 of FIG. 9. An RF field can be generated using the final RF signal and a RF excitation source, such as RF excitation source 330, 630, and applying the generated RF field to a magneto-optical defect center material, such as a NV diamond material 320, 620 or other magneto-optical defect center material. By modifying the generated RF field based on the desired magnetic field proxy modulation, the resulting detected optical signal will include the applied desired magnetic field proxy modulation, R(t), superimposed on top of any background environmental magnetic field signals present.

The process 1000 can include measuring a magnetic field with the desired magnetic field proxy modulation superimposed on the uncalibrated magnetic field (block 1030). The measured magnetic field can be calculated using magneto-optical defect center signal processing without reference to the superimposed desired magnetic field proxy modulation. That is, fluorescence intensities can be measured using an optical detector for each of a plurality of RF frequencies about the base RF wave. A magnetometry curve, such as the one shown in FIG. 8, can be generated based on the measured fluorescence intensities at each of the plurality of RF frequencies about the base RF wave. The magnetic field component, B_{z}, along the corresponding orientation class for the magnetometry curve can then be determined based on the resonance frequency relative to the zero external magnetic field frequency, such as 2.87 GHz, in a similar manner to that in FIG. 5. Because the resulting detected optical signal will include the desired magnetic field proxy modulation, R(t), superimposed on top of the uncalibrated magnetic field environmental magnetic field signals, the resulting magnetic field component, B_{z}, will also include the resulting proxy magnetic field corresponding to the desired magnetic field proxy modulation.

The process 1000 can include determining a processed proxy magnetic reference signal (block 1040). As noted above, the resulting detected optical signal includes the desired magnetic field proxy modulation, R(t), superimposed on top of the uncalibrated magnetic field environmental magnetic field signals, such that the resulting magnetic field component, B_{z}, will also include the resulting proxy magnetic field corresponding to the desired magnetic field proxy modulation. The processed proxy magnetic reference signal, b₁ estimate, can be determined by subtracting the uncalibrated magnetic field for the corresponding frequency from the resulting measured magnetic field from block 1030. In some implementations, the processed proxy magnetic reference signal can be determined for each of a plurality of RF frequencies by sequentially stepping through each frequency of a plurality of RF frequencies (f₁, f₂, . . . , fₙ). In some implementations, the processed proxy magnetic reference signal can be compared to a predetermined processed proxy magnetic reference signal and, if a difference between the processed proxy magnetic reference signal and the predetermined processed proxy magnetic reference signal is below a predetermined error value, such as 1% error, 5% error, 10% error, etc., then an initial pass/fail test flag can be set to a value corresponding to pass. If the difference between the processed proxy magnetic reference signal and the predetermined processed proxy magnetic reference signal is above the predetermined error value, then the initial pass/fail test flag can be set to a value corresponding to fail. Thus, the processed proxy magnetic reference signal can be used as an initialization test or check for a magnetometer.

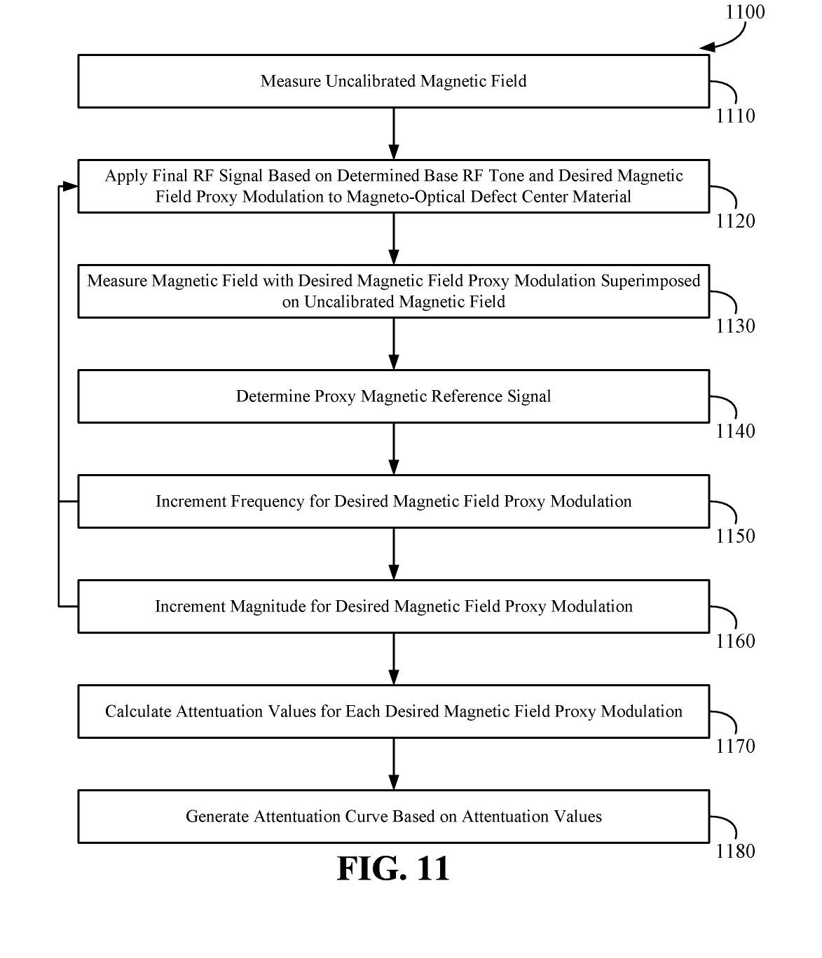

FIG. 11 illustrates a process 1100 for generating a sensor attenuation curve of external magnetic fields as a function of frequency using proxy magnetic field modulations. The process 1100 includes measuring an uncalibrated magnetic field (block 1110). The uncalibrated magnetic field can be measured by applying a Ramsey pulse sequence for each of a plurality of RF frequencies and storing a corresponding intensity output for each respective frequency of the plurality of RF frequencies. The corresponding baseline uncalibrated magnetic field data can be stored as a baseline curve.

The process 1100 can include applying a final RF signal based on a determined base RF wave and desired magnetic field proxy modulation to a magneto-optical defect center material (block 1120). The final RF signal can be determined based on the process 900 of FIG. 9. An RF field can be generated using the final RF signal and a RF excitation source, such as RF excitation source 330, 630, and applying the generated RF field to a magneto-optical defect center material, such as a NV diamond material 320, 620 or other magneto-optical defect center material.

The process 1100 can include measuring a magnetic field with the desired magnetic field proxy modulation superimposed on the uncalibrated magnetic field (block 1130). The measured magnetic field can be calculated using magneto-optical defect center signal processing without reference to the superimposed desired magnetic field proxy modulation. A magnetometry curve, such as the one shown in FIG. 8, can be generated based on the measured fluorescence intensities at each of the plurality of RF frequencies about the base RF wave. The magnetic field component, B_{z}, along the corresponding orientation class for the magnetometry curve can then be determined based on the resonance frequency relative to the zero external magnetic field frequency, such as 2.87 GHz, in a similar manner to that in FIG. 5. Because the resulting detected optical signal will include the desired magnetic field proxy modulation, R(t), superimposed on top of the uncalibrated magnetic field environmental magnetic field signals, the resulting magnetic field component, B_{z}, will also include the resulting proxy magnetic field corresponding to the desired magnetic field proxy modulation.

The process 1100 can include determining a processed proxy magnetic reference signal (block 1140). As noted above, the resulting detected optical signal includes the desired magnetic field proxy modulation, R(t), superimposed on top of the uncalibrated magnetic field environmental magnetic field signals, such that the resulting magnetic field component, B_{z}, will also include the resulting proxy magnetic field corresponding to the desired magnetic field proxy modulation. The processed proxy magnetic reference signal, b₁ estimate, can be determined by subtracting the uncalibrated magnetic field for the corresponding frequency from the resulting measured magnetic field from block 1130.

The process 1100 may include incrementing a frequency for a desired magnetic field proxy modulation (block 1150). Each of a plurality of RF frequencies (f₁, f₂, . . . , fₙ) are sequentially stepped through. The processed proxy magnetic reference signal, b₁ estimate, for each of the plurality of RF frequencies at the corresponding projected magnitude can be stored in a data storage device. The process 1100 also may include incrementing a magnitude for a desired magnetic field proxy modulation (block 1160). Each of a plurality of projected magnitudes (b₁, b₂, . . . , bₙ) are sequentially stepped through. The sets of processed proxy magnetic reference signals, b₁ estimate, for each of the projected magnitudes at the plurality of RF frequencies can be stored in a data storage device.

The process 1100 further can include calculating attenuation values for each desired magnetic field proxy modulation (block 1170). The attenuation values can be calculated as aᵢ=bᵢ/bᵢ estimate, where bᵢ is the set of projected magnitudes used to generate the corresponding desired magnetic field proxy modulation and bᵢ estimate is the set of processed proxy magnetic reference signals. In some implementations, the attenuation values can be stored in a data storage device as a look-up table. The attenuation values can be used to modify a measured magnetic field component to correct for attenuation at a corresponding frequency based on the stored attenuation values in the look-up table. In some implementations, the look-up table of attenuation values can be calculated and stored responsive to the sensor and corresponding data processing system being powered up. In other implementations, the look-up table of attenuation values can be calculated and stored at predetermined periods, such as after a period of 10 minutes, 30 minutes, 60 minutes, 2 hours, 3 hours, 6 hours, 12 hours, 24 hours, etc.

In some implementations, the process 1100 can include generating an attenuation curve based on the attenuation values (block 1180). The attenuation curve may be a plot of the look-up table attenuation values.

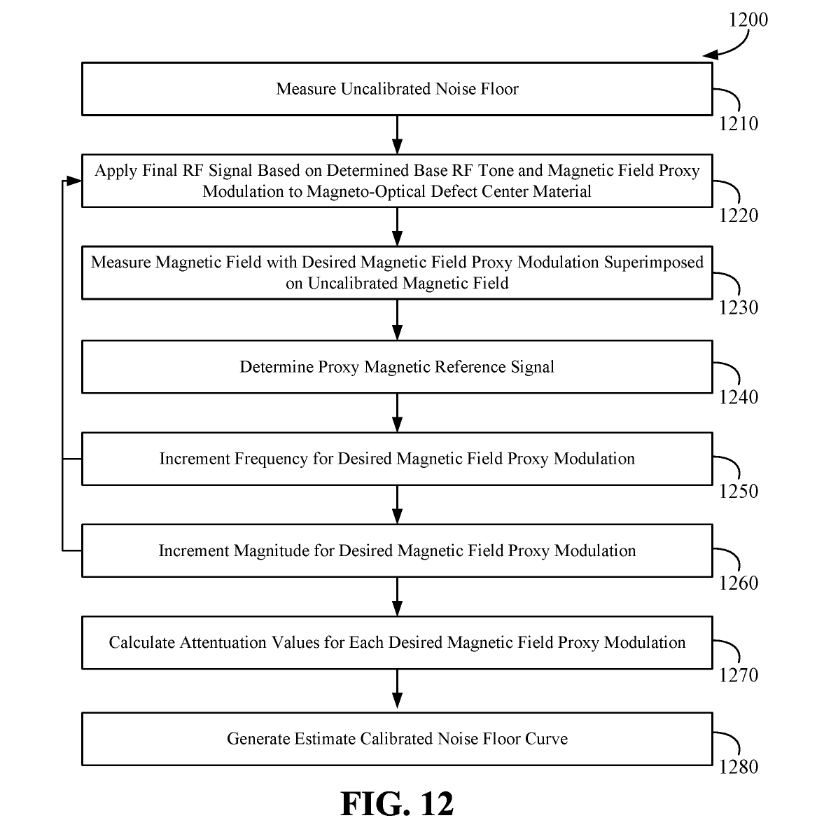

FIG. 12 illustrates a process 1200 for generating a calibrated noise floor as a function of frequency using magnetic field proxy modulation s. The process 1200 includes measuring an uncalibrated noise floor (block 1210). The uncalibrated noise floor can be measured by applying a Ramsey pulse sequence for each of a plurality of RF frequencies and storing a corresponding intensity output for each respective frequency of the plurality of RF frequencies and estimating a noise floor value, wᵢ, for each of the plurality of RF frequencies, fᵢ. The corresponding baseline uncalibrated noise floor estimates can be stored as a baseline curve.

The process 1200 can include applying a final RF signal based on a determined base RF wave and desired magnetic field proxy modulation to a magneto-optical defect center material (block 1220). The final RF signal can be determined based on the process 900 of FIG. 9. An RF field can be generated using the final RF signal and a RF excitation source, such as RF excitation source 330, 630, and applying the generated RF field to a magneto-optical defect center material, such as a NV diamond material 320, 620 or other magneto-optical defect center material.

The process 1200 can include measuring a magnetic field with the desired magnetic field proxy modulation superimposed on the uncalibrated magnetic field (block 1230). The measured magnetic field can be calculated using magneto-optical defect center signal processing without reference to the superimposed desired magnetic field proxy modulation. A magnetometry curve, such as the one shown in FIG. 8, can be generated based on the measured fluorescence intensities at each of the plurality of RF frequencies about the base RF wave. The magnetic field component, B_{z}, along the corresponding orientation class for the magnetometry curve can then be determined based on the resonance frequency relative to the zero external magnetic field frequency, such as 2.87 GHz, in a similar manner to that in FIG. 5. Because the resulting detected optical signal will include the desired magnetic field proxy modulation, R(t), superimposed on top of the uncalibrated magnetic field environmental magnetic field signals, the resulting magnetic field component, B_{z}, will also include the resulting proxy magnetic field corresponding to the desired magnetic field proxy modulation.

The process 1200 can include determining a processed proxy magnetic reference signal (block 1240). As noted above, the resulting detected optical signal includes the desired magnetic field proxy modulation, R(t), superimposed on top of the uncalibrated magnetic field environmental magnetic field signals, such that the resulting magnetic field component, B_{z}, will also include the resulting proxy magnetic field corresponding to the desired magnetic field proxy modulation. The processed proxy magnetic reference signal, b₁ estimate, can be determined by subtracting the uncalibrated magnetic field for the corresponding frequency from the resulting measured magnetic field from block 1130.

The process 1200 may include incrementing a frequency for a desired magnetic field proxy modulation (block 1250). Each of a plurality of RF frequencies (f₁, f₂, . . . , fₙ) are sequentially stepped through. The processed proxy magnetic reference signal, b₁ estimate, for each of the plurality of RF frequencies at the corresponding projected magnitude can be stored in a data storage device. The process 1200 also may include incrementing a magnitude for a desired magnetic field proxy modulation (block 1260). Each of a plurality of projected magnitudes (b₁, b₂, . . . , bₙ) are sequentially stepped through. The sets of processed proxy magnetic reference signals, b₁ estimate, for each of the projected magnitudes at the plurality of RF frequencies can be stored in a data storage device.

The process 1200 further can include calculating attenuation values for each desired proxy magnetic reference signal (block 1270). The attenuation values can be calculated as aᵢ=bᵢ/bᵢ estimate, where bᵢ is the set of projected magnitudes used to generate the corresponding desired biasing magnetic field proxy modulation and bᵢ estimate is the set of processed proxy magnetic reference signals. In some implementations, the attenuation values can be stored in a data storage device as a look-up table. The attenuation values can be used to modify a measured magnetic field component to correct for attenuation at a corresponding frequency based on the stored attenuation values in the look-up table. In some implementations, the look-up table of attenuation values can be calculated and stored responsive to the sensor and corresponding data processing system being powered up. In other implementations, the look-up table of attenuation values can be calculated and stored at predetermined periods, such as after a period of 10 minutes, 30 minutes, 60 minutes, 2 hours, 3 hours, 6 hours, 12 hours, 24 hours, etc.

In some implementations, the process 1200 can include generating an estimated calibrated noise floor curve based on the attenuation values (block 1280). Each estimated calibrated noise floor curve value may be calculated by vᵢ=wᵢaᵢ, where wᵢ is the uncalibrated noise floor value at a corresponding frequency and aᵢ is the corresponding attenuation value for the corresponding frequency. In some implementations, the estimated calibrated noise floor values may be stored in a look-up table calibrated noise floor values.

In some implementations, the projected magnitude, b₁, of the proxy magnetic field can be in a range of 100 picoTeslas to 1 microTesla, or, in some instances, 10 nanoTeslas to 100 nanoTeslas, in increments of 1 nanoTesla. In some implementations, the selected frequency, f₁, of the proxy magnetic field can vary based upon the application. For instance for magnetic location and/or navigation, a small frequency increment, such as 0 Hz, to a large frequency increment, such as 100 kHz, can be selected to increment. For magnetic communication, a medium frequency increment, such as 5 kHz to 10 kHz, can be selected to increment.

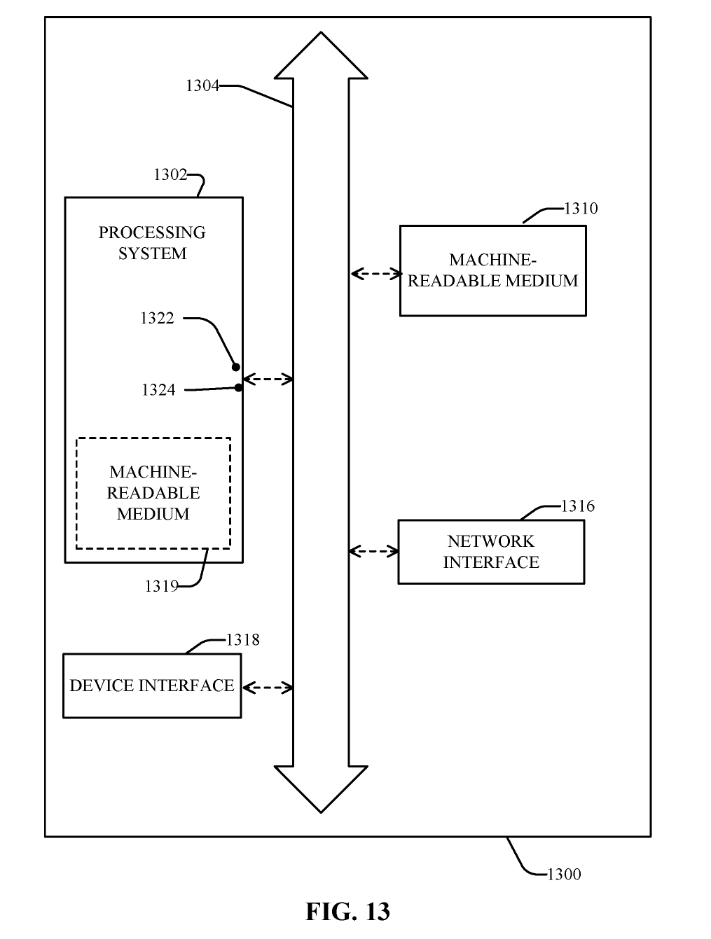

FIG. 13 is a diagram illustrating an example of a system 1300 for implementing some aspects such as the controller. The system 1300 includes a processing system 1302, which may include one or more processors or one or more processing systems. A processor may be one or more processors. The processing system 1302 may include a general-purpose processor or a specific-purpose processor for executing instructions and may further include a machine-readable medium 1319, such as a volatile or non-volatile memory, for storing data and/or instructions for software programs. The instructions, which may be stored in a machine-readable medium 1310 and/or 1319, may be executed by the processing system 1302 to control and manage access to the various networks, as well as provide other communication and processing functions. The instructions may also include instructions executed by the processing system 1302 for various user interface devices, such as a display 1312 and a keypad 1314. The processing system 1302 may include an input port 1322 and an output port 1324. Each of the input port 1322 and the output port 1324 may include one or more ports. The input port 1322 and the output port 1324 may be the same port (e.g., a bi-directional port) or may be different ports.

The processing system 1302 may be implemented using software, hardware, or a combination of both. By way of example, the processing system 1302 may be implemented with one or more processors. A processor may be a general-purpose microprocessor, a microcontroller, a Digital Signal Processor (DSP), an Application Specific Integrated Circuit (ASIC), a Field Programmable Gate Array (FPGA), a Programmable Logic Device (PLD), a controller, a state machine, gated logic, discrete hardware components, or any other suitable device that can perform calculations or other manipulations of information.

A machine-readable medium may be one or more machine-readable media, including no-transitory or tangible machine-readable media. Software shall be construed broadly to mean instructions, data, or any combination thereof, whether referred to as software, firmware, middleware, microcode, hardware description language, or otherwise. Instructions may include code (e.g., in source code format, binary code format, executable code format, or any other suitable format of code).

Machine-readable media (e.g., 1319) may include storage integrated into a processing system such as might be the case with an ASIC. Machine-readable media (e.g., 1310) may also include storage external to a processing system, such as a Random Access Memory (RAM), a flash memory, a Read Only Memory (ROM), a Programmable Read-Only Memory (PROM), an Erasable PROM (EPROM), registers, a hard disk, a removable disk, a CD-ROM, a DVD, or any other suitable storage device. Those skilled in the art will recognize how best to implement the described functionality for the processing system 1302. According to one aspect of the disclosure, a machine-readable medium is a computer-readable medium encoded or stored with instructions and is a computing element, which defines structural and functional interrelationships between the instructions and the rest of the system, which permit the instructions' functionality to be realized. Instructions may be executable, for example, by the processing system 1302 or one or more processors. Instructions can be, for example, a computer program including code for performing methods of some of the embodiments.

A network interface 1316 may be any type of interface to a network (e.g., an Internet network interface), and may reside between any of the components shown in FIG. 13 and coupled to the processor via the bus 1304.

A device interface 1318 may be any type of interface to a device and may reside between any of the components shown in FIG. 13. A device interface 1318 may, for example, be an interface to an external device (e.g., USB device) that plugs into a port (e.g., USB port) of the system 1300.

One or more of the above-described features and applications may be implemented as software processes that are specified as a set of instructions recorded on a computer readable storage medium (alternatively referred to as computer-readable media, machine-readable media, or machine-readable storage media). When these instructions are executed by one or more processing unit(s) (e.g., one or more processors, cores of processors, or other processing units), they cause the processing unit(s) to perform the actions indicated in the instructions. In one or more implementations, the computer readable media does not include carrier waves and electronic signals passing wirelessly or over wired connections, or any other ephemeral signals. For example, the computer readable media may be entirely restricted to tangible, physical objects that store information in a form that is readable by a computer. In one or more implementations, the computer readable media is non-transitory computer readable media, computer readable storage media, or non-transitory computer readable storage media.

In one or more implementations, a computer program product (also known as a program, software, software application, script, or code) can be written in any form of programming language, including compiled or interpreted languages, declarative or procedural languages, and it can be deployed in any form, including as a stand-alone program or as a module, component, subroutine, object, or other unit suitable for use in a computing environment. A computer program may, but need not, correspond to a file in a file system. A program may be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program may be deployed to be executed on one computer or on multiple computers that are located at one site or distributed across multiple sites and interconnected by a communication network.

While the above discussion primarily refers to microprocessor or multi-core processors that execute software, one or more implementations are performed by one or more integrated circuits, such as application specific integrated circuits (ASICs) or field programmable gate arrays (FPGAs). In one or more implementations, such integrated circuits execute instructions that are stored on the circuit itself.

The description is provided to enable any person skilled in the art to practice the various embodiments described herein. While some embodiments have been particularly described with reference to the various figures and configurations, it should be understood that these are for illustration purposes only and should not be taken as limiting the scope of the subject technology.

There may be many other ways to implement. Various functions and elements described herein may be partitioned differently from those shown without departing from the scope of the subject technology. Various modifications to these embodiments may be readily apparent to those skilled in the art, and generic principles defined herein may be applied to other embodiments. Thus, many changes and modifications may be made by one having ordinary skill in the art, without departing from the scope of the subject technology.

A reference to an element in the singular is not intended to mean “one and only one” unless specifically stated, but rather “one or more.” The term “some” refers to one or more. Underlined and/or italicized headings and subheadings are used for convenience only, do not limit the subject technology, and are not referred to in connection with the interpretation of the description of the subject technology. All structural and functional equivalents to the elements of the various embodiments described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description.

What is claimed is:

1. A system comprising:
a magnetometer including:
a magneto-optical defect center material,
an optical excitation source,
a radiofrequency (RF) excitation source, and
an optical sensor; and
a controller, the controller configured to:
activate the RF excitation source to apply a RF field to the magneto-optical defect center material at a plurality of RF frequencies;
identify a RF reference frequency where the magneto-optical defect center material produces an increased rate of change in luminescence for an incremental change in RF frequency of the RF wave
activate a radiofrequency (RF) pulse sequence for the RF excitation source to apply a RF field to the magneto-optical defect center material, the RF pulse sequence based on a magnetic field proxy modulation and a base RF wave, wherein the magnetic field proxy modulation is indicative of a proxy magnetic field,
activate an optical pulse sequence for the optical excitation source to apply a laser pulse to the magneto-optical defect center material,
acquire in conjunction with the optical pulse sequence a magnetic field measurement from the magneto-optical defect center material using the optical sensor, wherein the magnetic field measurement comprises a proxy magnetic field based on the magnetic field proxy modulation.

2. The system of claim 1, wherein the magnetic field proxy modulation is a sinusoidal magnetic field proxy modulation.

3. The system of claim 2, wherein the sinusoidal magnetic field proxy modulation is calculated based on γb₁ sin(2πf₁t), where γ is an electron gyromagnetic ratio for the magneto-optical defect center material, b₁ is a selected projected magnitude for the proxy magnetic field, and f₁ is selected frequency for the proxy magnetic field.

4. The system of claim 3, wherein the selected projected magnitude for the proxy magnetic field is between 100 picoTeslas and 1 microTesla.

5. The system of claim 3, wherein the selected frequency for the proxy magnetic field is between 0 Hz and 100 kHz.

6. The system of claim 1, wherein the magnetic field measurement comprises magnetic communication data.

7. The system of claim 1, wherein the magnetic field measurement comprises magnetic navigation data.

8. The system of claim 1, wherein the magnetic field measurement comprises magnetic location data.

9. The system of claim 1, wherein the magneto-optical defect center material comprises a diamond having nitrogen vacancies.

10. A method for operating a magnetometer having a magneto-optical defect center material, the method comprising:
activating a radiofrequency (RF) pulse sequence to apply an RF field to the magneto-optical defect center material, the RF pulse sequence based on a magnetic field proxy modulation and a base RF wave, wherein the magnetic field proxy modulation is indicative of a proxy magnetic field; and
acquiring a magnetic field measurement using the magneto-optical defect center material, wherein the magnetic field measurement comprises a proxy magnetic field based on the magnetic field proxy modulation.

11. The method of claim 10, wherein the magnetic field proxy modulation is a sinusoidal magnetic field proxy modulation.

12. The method of claim 11, wherein the sinusoidal magnetic field proxy modulation is calculated based on γb₁ sin(2πf₁t), where γ is an electron gyromagnetic ratio for the magneto-optical defect center material, b₁ is a selected projected magnitude for the proxy magnetic field, and f₁ is selected frequency for the proxy magnetic field.

13. The method of claim 12, wherein the selected projected magnitude for the proxy magnetic field is between 100 picoTeslas and 1 microTesla.

14. The method of claim 12, wherein the selected frequency for the proxy magnetic field is between 0 Hz and 100 kHz.

15. The method of claim 10, wherein the magnetic field measurement comprises magnetic communication data.

16. The method of claim 10, wherein the magnetic field measurement comprises magnetic navigation data.

17. The method of claim 10, wherein the magnetic field measurement comprises magnetic navigation data.

18. The method of claim 10, wherein the magneto-optical defect center material comprises a diamond having nitrogen vacancies.

19. A sensor comprising:
a magneto-optical defect center material;
a radiofrequency (RF) excitation source; and
a controller configured to:
activate a radiofrequency (RF) pulse sequence for the RF excitation source to apply a RF field to the magneto-optical defect center material, the RF pulse sequence based on a biasing RF modulation and a base RF wave, wherein the biasing RF modulation is indicative of a proxy magnetic field, and
acquire a magnetic field measurement from the magneto-optical defect center material, wherein the magnetic field measurement comprises a proxy magnetic field based on the biasing RF modulation.

20. The sensor of claim 19, wherein the biasing RF modulation is a sinusoidal biasing RF modulation.

21. The sensor of claim 20, wherein the sinusoidal biasing RF modulation is calculated based on γb₁ sin(2πf₁t), where γ is an electron gyromagnetic ratio for the magneto-optical defect center material, b₁ is a selected projected magnitude for the proxy magnetic field, and f₁ is selected frequency for the proxy magnetic field.

22. The sensor of claim 21, wherein the selected projected magnitude for the proxy magnetic field is between 100 picoTeslas and 1 microTesla.

23. The sensor of claim 21, wherein the selected frequency for the proxy magnetic field is between 0 Hz and 100 kHz.

24. A magnetometer comprising:
a magneto-optical defect center material;
a radiofrequency (RF) excitation source;
an optical sensor; and
a controller, the controller configured to:
activate a radiofrequency (RF) pulse sequence for the RF excitation source to apply a RF field to the magneto-optical defect center material, the RF pulse sequence based on a magnetic field proxy modulation and a base RF wave, wherein the magnetic field proxy modulation is indicative of a proxy magnetic field,
acquire a magnetic field measurement from the magneto-optical defect center material using the optical sensor, wherein the magnetic field measurement comprises a proxy magnetic field based on the magnetic field proxy modulation, and
set a value for a flag indicative of passing an initial pass/fail test based on a processed proxy magnetic reference signal determined from the magnetic field measurement.

25. The system of claim 24, wherein the magnetic field proxy modulation is a sinusoidal magnetic field proxy modulation.

26. The system of claim 25, wherein the sinusoidal magnetic field proxy modulation is calculated based on γb₁ sin(2πf₁t), where γ is an electron gyromagnetic ratio for the magneto-optical defect center material, b₁ is a selected projected magnitude for the proxy magnetic field, and f₁ is selected frequency for the proxy magnetic field.

27. The system of claim 26, wherein the selected projected magnitude for the proxy magnetic field is between 100 picoTeslas and 1 microTesla.

28. The system of claim 26, wherein the selected frequency for the proxy magnetic field is between 0 Hz and 100 kHz.

29. A magnetometer comprising:
a magneto-optical defect center material;
a radiofrequency (RF) excitation source;
an optical sensor; and
a controller, the controller configured to:
activate a radiofrequency (RF) pulse sequence for the RF excitation source to apply a RF field to the magneto-optical defect center material, the RF pulse sequence based on a magnetic field proxy modulation and a base RF wave, wherein the magnetic field proxy modulation is indicative of a proxy magnetic field,
acquire a magnetic field measurement from the magneto-optical defect center material using the optical sensor, wherein the magnetic field measurement comprises a proxy magnetic field based on the magnetic field proxy modulation, and
determine an attenuation value based on a processed proxy magnetic reference signal determined from the magnetic field measurement.

30. The system of claim 29, wherein the magnetic field proxy modulation is a sinusoidal magnetic field proxy modulation.

31. The system of claim 30, wherein the sinusoidal magnetic field proxy modulation is calculated based on γb₁ sin(2πf₁t), where γ is an electron gyromagnetic ratio for the magneto-optical defect center material, b₁ is a selected projected magnitude for the proxy magnetic field, and f₁ is selected frequency for the proxy magnetic field.

32. The system of claim 31, wherein the selected projected magnitude for the proxy magnetic field is between 100 picoTeslas and 1 microTesla.

33. The system of claim 31, wherein the selected frequency for the proxy magnetic field is between 0 Hz and 100 kHz.

34. A magnetometer comprising:
a magneto-optical defect center material;
a radiofrequency (RF) excitation source;
an optical sensor; and
a controller, the controller configured to:
activate a radiofrequency (RF) pulse sequence for the RF excitation source to apply a RF field to the magneto-optical defect center material, the RF pulse sequence based on a magnetic field proxy modulation and a base RF wave, wherein the magnetic field proxy modulation is indicative of a proxy magnetic field,
acquire a magnetic field measurement from the magneto-optical defect center material using the optical sensor, wherein the magnetic field measurement comprises a proxy magnetic field based on the magnetic field proxy modulation, and
determine an estimated calibrated noise floor value based on a processed proxy magnetic reference signal determined from the magnetic field measurement.

35. The system of claim 34, wherein the magnetic field proxy modulation is a sinusoidal magnetic field proxy modulation.

36. The system of claim 35, wherein the sinusoidal magnetic field proxy modulation is calculated based on γb₁ sin(2πf₁t), where γ is an electron gyromagnetic ratio for the magneto-optical defect center material, b₁ is a selected projected magnitude for the proxy magnetic field, and f₁ is selected frequency for the proxy magnetic field.

37. The system of claim 36, wherein the selected projected magnitude for the proxy magnetic field is between 100 picoTeslas and 1 microTesla.

38. The system of claim 36, wherein the selected frequency for the proxy magnetic field is between 0 Hz and 100 kHz.

39. A system comprising:
a magneto-optical defect center material;
an excitation source;
an optical sensor; and
a controller, the controller configured to:
activate an energy pulse sequence for the excitation source to apply energy to the magneto-optical defect center material, the energy pulse sequence based on a magnetic field proxy modulation and a base signal, wherein the magnetic field proxy modulation is indicative of a proxy magnetic field, and
acquire a magnetic field measurement from the magneto-optical defect center material using the optical sensor, wherein the magnetic field measurement comprises a proxy magnetic field based on the magnetic field proxy modulation.

40. The system of claim 39, wherein the magnetic field proxy modulation is a sinusoidal magnetic field proxy modulation.

41. The system of claim 40, wherein the sinusoidal magnetic field proxy modulation is calculated based on γb₁ sin(2πf₁t), where γ is an electron gyromagnetic ratio for the magneto-optical defect center material, b₁ is a selected projected magnitude for the proxy magnetic field, and f₁ is selected frequency for the proxy magnetic field.

42. The system of claim 41, wherein the selected projected magnitude for the proxy magnetic field is between 100 picoTeslas and 1 microTesla.

43. The system of claim 41, wherein the selected frequency for the proxy magnetic field is between 0 Hz and 100 kHz.

44. A sensor comprising:
a magneto-optical defect center material;
a radiofrequency (RF) excitation source; and
a controller configured to:
activate a radiofrequency (RF) wave scan to identify a RF reference frequency where the magneto-optical defect center material produces an increased rate of change in luminescence for an incremental change in RF frequency of the RF wave.
activate a pulse sequence for the RF excitation source to apply a RF field to the magneto-optical defect center material, the RF frequency of the pulse sequence correlating to the RF reference frequency altered by a magnetic field proxy modulation whose energy is correlated to a proxy magnetic field, and
acquire a magnetic field measurement from the magneto-optical defect center material, wherein the magnetic field measurement comprises the proxy magnetic field based on the magnetic field proxy modulation.

45. The sensor of claim 44, wherein the magnetic field proxy modulation and the pulse sequence are generated by separate RF excitation sources.

46. The sensor of claim 44, wherein an RF frequency of the pulse sequence is modified by increasing the RF frequency by a biasing RF frequency based on the magnetic field proxy modulation.

47. The sensor of claim 44, wherein the biasing RF frequency is determined based on a single order transfer relationship to the proxy magnetic field.
